(19) United States
(12) Patent Application Publication
(10) Pub. No.: US 2026/0107379 A1
(43) Pub. Date: Apr. 16, 2026

(54) PRINTED CIRCUIT BOARD

(71) Applicant: SAMSUNG ELECTRO-MECHANICS CO., LTD., Suwon-si (KR)

(72) Inventors: Sang Ho Jeong, Suwon-si (KR); Chang Hwa Park, Suwon-si (KR); Sang Yun Lee, Suwon-si (KR); Hyun Hu Lee, Suwon-si (KR)

(73) Assignee: SAMSUNG ELECTRO-MECHANICS CO., LTD., Suwon-si (KR)

(21) Appl. No.: 19/172,155

(22) Filed: Apr. 7, 2025

(30) Foreign Application Priority Data
Oct. 10, 2024 (KR) 10-2024-0137711

(51) Int. Cl. H05K 1/03; H05K 1/11

(52) U.S. Cl. CPC H05K 1/0306; H05K 1/115

(57) ABSTRACT

a printed circuit board comprises a glass layer with a first surface and a second surface opposing one another along a thickness direction, and a side surface connecting the first and second surfaces. A metal layer is disposed on the side surface of the glass layer, and a first insulating layer is disposed on the first and side surfaces such that it covers the metal layer. This configuration enhances electromagnetic shielding and mitigates crack propagation in the glass layer, thereby improving the reliability of the printed circuit board.

### CROSS-REFERENCE TO RELATED APPLICATIONS

This application claims benefit of priority to Korean Patent Application No. 10-2024-0137711, filed on Oct. 10, 2024 with the Korean Intellectual Property Office, the disclosure of which is incorporated herein by reference in its entirety.

### BACKGROUND

### 1. Field The present disclosure relates to a printed circuit board.

### 2. Description of Related Art

Recently, to improve performance of a printed circuit board, large area, multilayer, and miniaturization may be necessary. A copper clad laminate (CCL) may be used as a core layer included in a printed circuit board, but warpage may easily occur due to a low modulus and a high coefficient of thermal expansion, and there may be limitations in implementing a microcircuit. Accordingly, warpage may be prevented, and demand for a new material which may easily implement a microcircuit, such as a glass substrate, has increased. However, in the case of a glass substrate, an outer edge of a panel may be damaged depending on handling or equipment operation during a process of manufacturing a substrate, and accordingly, cracks may be formed in a unit region, yield may be reduced.

### SUMMARY

An aspect of the present disclosure is to provide a printed circuit board that may reduce cracks in a glass layer.

According to an example embodiment, a printed circuit board includes a glass layer having a first surface and a second surface opposing each other in a thickness direction, and a side surface connected to the first surface and the second surface; a metal layer disposed on a side surface of the glass layer; and a first insulating layer disposed on the first surface and the side surface of the glass layer, wherein the first insulating layer covers the metal layer on the side surface of the glass layer.

The metal layer may be disposed on at least a portion of the first and second surfaces of the glass layer.

The first insulating layer may be disposed in a region of the side surface of the glass layer, in which the metal layer is not disposed.

An area of the metal layer, covering the side surface of the glass layer, may be greater than that of the first insulating layer.

A region of the side surface of the glass layer wherein the metal layer is not disposed, may be inclined relative to the thickness direction.

A region of the side surface of the glass layer, in which the metal layer is not disposed, may include a plurality of regions having different angles of inclination with respect to the thickness direction.

A region of a side surface of the glass layer, in which the metal layer is not disposed, may have a shape in which a width of the glass layer increases and then decreases in a direction from the first surface to the second surface.

A region of the side surface of the glass layer wherein the metal layer is not disposed, may be more inclined in the thickness direction than a region in which the metal layer is disposed.

The printed circuit board may further include a second insulating layer disposed on the second surface and the side surface of the glass layer.

An area of the metal layer, covering the side surface of the glass layer, may be greater than that of the second insulating layer.

The metal layer may be separated from the side surface of the glass layer by the second insulating layer.

Within the second insulating layer, a region disposed on a side surface of the glass layer may include a plurality of regions separated from each other.

Side surfaces of the first and second insulating layers may be coplanar with each other.

The first insulating layer and the second insulating layer may comprise the same material and may be in contact with each other while forming an interfacial surface.

The glass layer may include a protrusion formed on the side surface.

According to an example embodiment, a printed circuit board includes a glass layer having a first surface and a second surface opposing each other in a thickness direction, and a side surface connected to the first surface and the second surface; a metal layer disposed in a first region of the side surface of the glass layer; and an insulating layer including a material different from that of the glass layer and disposed in a second region of the side surface of the glass layer.

An area of the first region may be larger than an area of the second region.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram illustrating an example of an electronic device system;

FIG. 2 is a perspective diagram illustrating an example of an electronic device;

FIG. 3 is a cross-sectional diagram illustrating an example of a printed circuit board;

FIGS. 4 to 12 are cross-sectional diagrams illustrating an example of a process for manufacturing a printed circuit board according an example embodiment;

FIGS. 13 and 14 are diagrams illustrating another example of a process for manufacturing a printed circuit board according an example embodiment;

FIG. 15 is a cross-sectional diagram illustrating another example of a printed circuit board according an example embodiment; and

FIG. 16 is a cross-sectional diagram illustrating another example of a printed circuit board according an example embodiment.

### DETAILED DESCRIPTION

Hereinafter, embodiments of the present disclosure will be described with reference to the accompanying drawings.

The present disclosure is not limited to exemplary embodiments, and it is to be understood that various modifications may be made without departing from the spirit and scope of the present disclosure. These embodiments are described in sufficient detail to enable those skilled in the art to practice the invention. Some elements may be exaggerated in the drawings, and the same elements will be indicated by the same reference numerals.

### Electronic Device

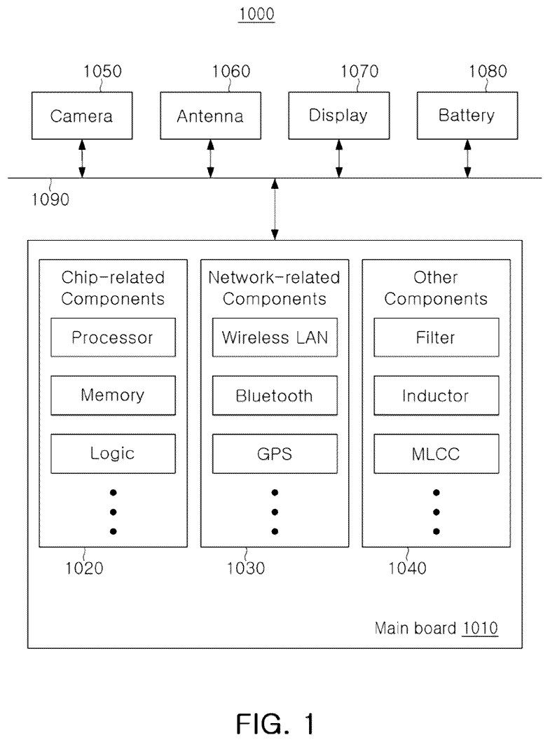

FIG. 1 is a block diagram illustrating an example of an electronic device system.

Referring to FIG. 1, an electronic device 1000 may incorporate a mainboard 1010 therein. The mainboard 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, and may also include other types of chip related components. Also, the chip related components 1020 may be combined with each other.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+ (HSPA+), high speed downlink packet access+ (HSDPA+), high speed uplink packet access+ (HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, and may also include a variety of other wireless or wired standards or protocols. Also, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, and may also include passive components used for various other purposes, or the like. Also, other components 1040 may be combined with each other, together with the chip related components 1020 and/or the network related components 1030 described above.

Depending on a type of the electronic device 1000, the electronic device 1000 may include other components which may or may not be physically or electrically connected to the mainboard 1010. These additional components may include, for example, a camera module 1050, an antenna module 1060, a display 1070, and a battery 1080. However, these components are not limited thereto and may include an audio codec, a video codec, a power amplifier, a compass, an accelerometer, a gyroscope, a speaker, a mass storage unit (for example, a hard disk drive), a compact disc (CD) drive, a digital versatile disc (DVD) drive, or the like. They may also include other components for various purposes, depending on the type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device processing data.

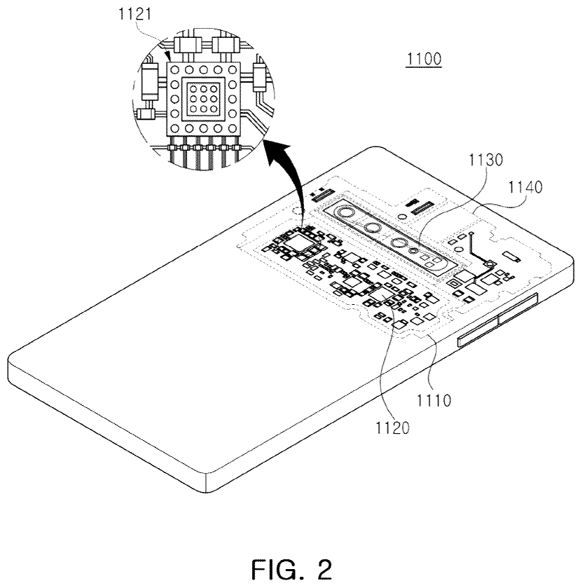

FIG. 2 is a plan diagram illustrating an example of an electronic device.

Referring to FIG. 2, an electronic device may be a smartphone 1100. A motherboard 1110 may be accommodated in the smartphone 1100, and various components 1120 may be physically or electrically connected to the motherboard 1110. Also, other components which may or may not be physically or electrically connected to the motherboard 1110, such as a camera module 1130, may be accommodated in the body 1101. A portion of the components 1120 may be the chip related components, such as, for example, a component package 1121, but an example embodiment example thereof is not limited thereto. The component package 1121 may have the form of a printed circuit board on which electronic components including active components and/or passive components are surface-mounted. Alternatively, the component package 1121 may be configured in the form of a printed circuit board in which active components and/or passive components are buried. The electronic device is not necessarily limited to the smartphone 1100, and may be other electronic devices as described above.

### Printed Circuit Board

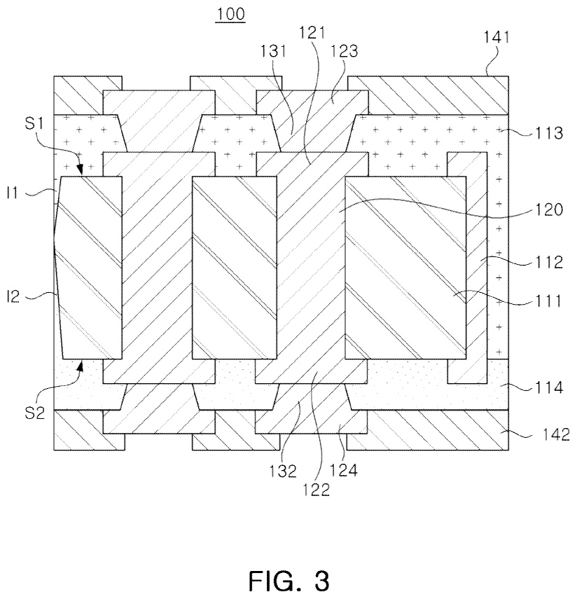

FIG. 3 is a cross-sectional diagram illustrating an example of a printed circuit board. Referring to FIG. 3, a printed circuit board 100 according to an embodiment may include a glass layer 111, a metal layer 112 and a first insulating layer 113. Here, the metal layer 112 may be disposed on a side surface of the glass layer 111, and the first insulating layer 113 may be disposed on a first surface S1 and a side surface of the glass layer 111, and may cover the metal layer 112 on the side surface of the glass layer 111. Also, the printed circuit board 100 may further include a second insulating layer 114, a via conductor 120, conductor layers 121, 122, 123, and 124, connection vias 131 and 132, passivation layers 141 and 142, or the like. The above-described structure may reduce propagation of cracks in an outer region of a panel to the glass layer 111 of the unit substrate region (unit region) during a process of manufacturing the printed circuit board 100, and further, as the metal layer 112 is disposed on the side surface of the glass layer 111, the electromagnetic shielding effect may be improved. Hereinafter, the main components of the printed circuit board 100 may be described in greater detail.

The glass layer 110 may include glass, which is an amorphous solid. The glass may include, for example, pure silicon dioxide (about 100% SiO₂), soda-lime glass, borosilicate glass, alumino-silicate glass, or the like. However, the embodiment is not limited thereto, and an alternative glass material—such as fluoride glass, phosphate glass, or chalcogenide glass—may also be used. Additionally, other additives may be included to form a glass with specific physical properties. Such additives may include calcium carbonate (e.g., lime) and sodium carbonate (e.g., soda), as well as magnesium, calcium, manganese, aluminum, lead, boron, iron, chromium, potassium, sulfur, and antimony, and the carbonates and/or oxides of these and other elements. The glass layer 110 may be distinguished from insulating materials that include glass fiber (glass cloth or glass fabric), such as copper clad laminate (CCL) or prepreg (PPG). For example, the glass layer 110 may comprise a glass plate (GC).

The glass layer 111 may have a first surface S1 and a second surface S2 opposing each other in the thickness direction (vertical direction based on the drawing), as well as a side surface connected to surfaces S1 and S2. The metal layer 112 may be disposed on the side surface of the glass layer 111 and, additionally, on at least a portion of surfaces S1 and S2; in one embodiment, the metal layer 112 is disposed on portions of both S1 and S2. Furthermore, the metal layer 112 may be disposed on a portion of the side surface, while at least one of the first insulating layer 113 and the second insulating layer 114 is disposed on the remaining portion. In this case, the area of the first region on the side surface of the glass layer 111, where the metal layer 112 is disposed, may be larger than the area of the second region where at least one of the insulating layers is disposed. This is because the first and second insulating layers 113 and 114, which comprise materials different from the glass layer 111, may be formed on the bridge region B required in the manufacturing process, whereas the metal layer 112 is formed on the other region of the side surface. By forming the metal layer 112 over a sufficiently large area, the electromagnetic shielding effect may be improved.

The metal layer 112 may be formed on the surface of the glass layer 111 through a plating process, and may be implemented in a multilayer structure including a seed layer and a plating layer. As an example of a material, the metal layer 112 may include copper (Cu), aluminum (Al), silver (Ag), tin (Sn), gold (Au), nickel (Ni), lead (Pb), titanium (Ti), and/or an alloy thereof. Preferably, the metal layer 112 may include copper (Cu), but an embodiment thereof is not limited thereto. In the embodiment, the metal layer 112 may be formed in a region other than a bridge region connected to an adjacent unit or an outer region of the panel of the side surface of the glass layer 111 in the manufacturing process described below. By covering the side surface of the glass layer 111, the metal layer 112 may have an electromagnetic shielding function, and accordingly, reliability of the printed circuit board 100 may be improved.

The first insulating layer 113 may be disposed on the first surface S1 and the side surface of the glass layer 111, and may cover the metal layer 112 on the side surface of the glass layer 111. Also, the first insulating layer 113 may also be disposed in a region of the side surface of the glass layer 111 in which the metal layer 112 is not disposed. In this case, the metal layer 112 may have a larger area covering the side surface of the glass layer 111 than that of the first insulating layer 113. The region of the side surface of the glass layer 111 in which the metal layer 112 is not disposed may have an inclined shape with respect to the thickness direction, and the first insulating layer 113 may be disposed in this inclined region I1. As a more specific example, the region of the side surface of the glass layer 111 in which the metal layer 112 is not disposed may include a plurality of regions I1 and I2 having different angles of inclination with respect to the thickness direction. Also, the region of the side surface of the glass layer 111 in which the metal layer 112 is not disposed may have a shape in which the width of the glass layer 111 increases and then decreases in a direction from the first surface S1 to the second surface S2. Also, the region of the side surface of the glass layer 111 in which the metal layer 112 is not disposed may be more inclined in the thickness direction than the region in which the metal layer 112 is disposed. The inclined structure may be obtained by adjusting the shape of the through-hole of the bridge region B in the process of forming a through-hole in the outer region of the unit region as described later.

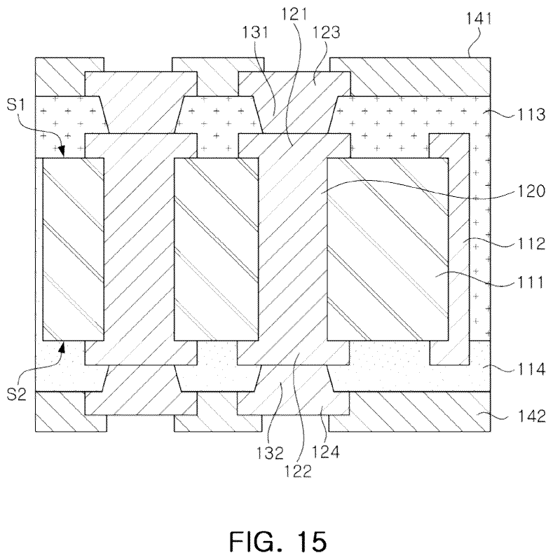

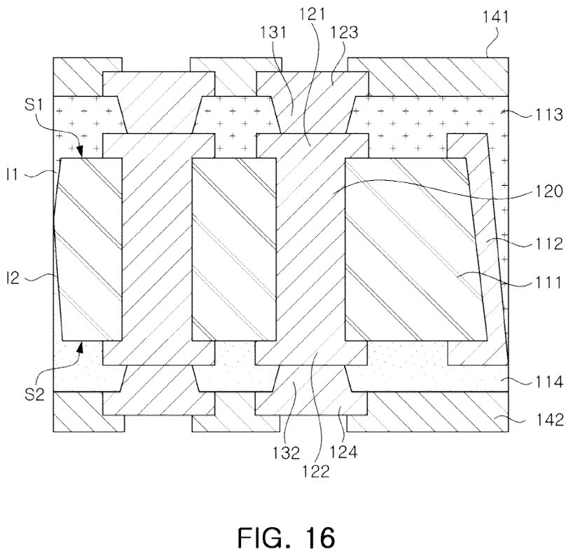

However, as in the modified example in FIG. 15, the region of the side surface of the glass layer 111 in which the metal layer 112 is not disposed may be formed as a substantially parallel plane without being inclined in the thickness direction, and this may be implemented by adjusting the shape of the through-hole. Also, as in the modified example in FIG. 16, the metal layer 112 of the side surface of the glass layer 111 may be formed as an inclined surface rather than a substantially parallel surface with respect to the thickness direction.

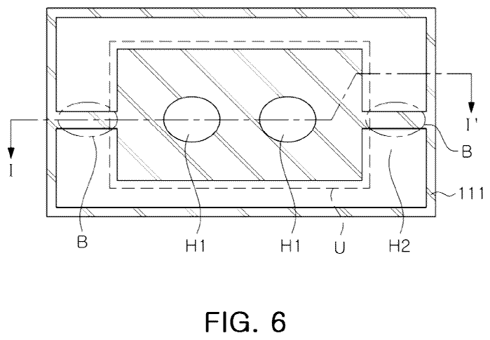

Referring again to FIG. 3, the second insulating layer 114 may be disposed on the second surface S2 and the side surface of the glass layer 111. In this case, the metal layer 112 may have a larger area covering the side surface of the glass layer 111 than that of the second insulating layer 114. Here, the second insulating layer 114 may cover a portion of the side surface of the glass layer 111, and the metal layer 113 may cover the other entire region of the side surface of the glass layer 111. Also, the metal layer 112 may be separated from the side surface of the glass layer 111 by the second insulating layer 114. As a more specific example, the region disposed on the side surface of the glass layer 111 in the second insulating layer 114 may include a plurality of regions separated from each other, and accordingly, the metal layer 112 may be divided into a plurality of regions. The second insulating layer 114 may be formed by removing the bridge region (B in FIG. 6) connected to the adjacent other unit or the outer region of the panel of the glass layer 111, and filling an insulating material as in the process described later.

As illustrated, the side surfaces of the first and second insulating layers 113 and 114 may be coplanar. This coplanar structure may be achieved during the formation of the first and second insulating layers 113 and 114 and by cutting the layers into units, as described later. The first insulating layer 113 and the second insulating layer 114 may comprise the same material and be in contact with each other, forming an interfacial surface.

The first insulating layer 113 and the second insulating layer 114 may include a material different from that of the glass layer 111, for example, an organic insulating material. The organic insulating material may include a thermosetting resin such as an epoxy resin, a thermoplastic resin such as a polyimide, or a resin together with an inorganic filler, an organic filler, and/or glass fiber, glass cloth, or glass fabric. For example, the organic insulating material may be a prepreg (PPG), an Ajinomoto build-up film (ABF), a photo imageable dielectric (PID), a solder resist (SR), or the like, but an embodiment thereof is not limited thereto. When desired, each of the first and second insulating layers 113 and 114 may be composed of a plurality of layers.

Each of the first through fourth conductor layers 121, 122, 123, and 124 may comprise a metal. The metal may comprise copper (Cu), aluminum (Al), silver (Ag), tin (Sn), gold (Au), nickel (Ni), lead (Pb), titanium (Ti), and/or alloys thereof. Preferably, copper (Cu) may be included, but an embodiment thereof is not limited thereto. Each of the first to fourth conductor layers 121, 122, 123, and 124 may perform various functions depending on the design. For example, the layers may include a signal pattern, a power pattern, a ground pattern, and the like. Each of these patterns may have various shapes such as a line, a plane, and a pad. Each of the first to fourth conductor layers 121, 122, 123, and 124 may include a seed layer and a plating layer. The seed layer may be formed by electroless plating (e.g., chemical copper), and when desired, the seed layer may be formed by a sputtering process. Alternatively, both processes may be used. The plating layer may be formed by electrolytic plating (e.g., electrolytic copper). When the first and second insulating layers 113, 114 are formed as plurality of layers, the first to fourth conductor layers 121, 122, 123, and 124 may be formed as a plurality of layers corresponding to the first and second insulating layers 113 and 114. The first to fourth conductor layers 121, 122, 123, and 124 may protrude on the first and second insulating layers 113 and 114, respectively, but may also be buried in the first and third insulating layers 113 and 114, respectively.

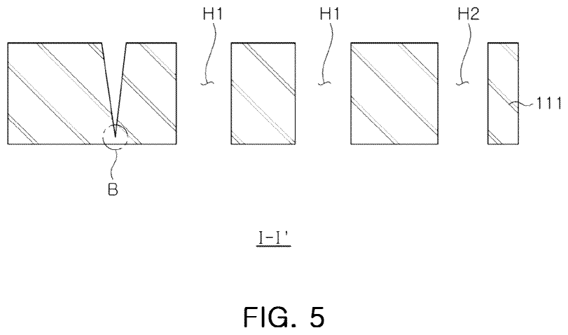

The via conductor 120 may include a metal. The metal may include copper (Cu), aluminum (Al), silver (Ag), tin (Sn), gold (Au), nickel (Ni), lead (Pb), titanium (Ti), and/or alloys thereof. Preferably, the via conductor 120 may include copper (Cu), but an embodiment thereof is not limited thereto. The via conductor 120 may be formed by filling a conductive material in the first through-hole (H1 in FIG. 5). The via conductor 120 may perform various functions depending on the design. For example, the via conductor 120 may include a signal via, a power via, a ground via, or the like. The via conductor 120 may be connected to each of the first and second conductor layers 121 and 122. The via conductor 120 may include a seed layer and a plating layer. The seed layer may be formed by electroless plating (e.g., chemical copper), or, if desired, by a sputtering process. Alternatively, both processes may be used. The plating layer may be formed by electrolytic plating (e.g., electrolytic copper).

Each of the first and second connection vias 131 and 132 may include a metal. The metal may include copper (Cu), aluminum (Al), silver (Ag), tin (Sn), gold (Au), nickel (Ni), lead (Pb), titanium (Ti), and/or alloys thereof. Preferably, the vias may include copper (Cu), but an embodiment thereof is not limited thereto. Each of the first and second connection vias 131 and 132 may perform various functions depending on the design. For example, the vias may include a signal via, a power via, a ground via, or the like. Each of the first and second connection vias 131 and 132 may include a filled via (filled VIA) in which a via hole is filled with a metal, but if desired, the vias may also include a conformal via (conformal VIA) in which a metal is disposed along the wall surface of the via hole. Each of the first and second connection vias 131 and 132 may have a tapered shape in cross-section. For example, the first connection via 131 may have a wider width at an upper end than at a lower end in the cross-section, and the second connection via 132 may have a wider width at the upper end than at the lower end in the cross-section. Each of the first and second connection vias 131 and 132 may include the seed layer and the plating layer included in the third and fourth conductor layers 123 and 124, respectively. The number of each of the first and second connection vias 131 and 132 may be plural.

The first and second resist layers 141 and 142 may have an opening which opens the conductor layer and may include an organic insulating material. Here, the organic insulating material may include a thermosetting resin such as an epoxy resin, a thermoplastic resin such as a polyimide, or a resin together with an inorganic filler, an organic filler, and/or glass fiber, glass cloth, or glass fabric. For example, the organic insulating material may be prepreg (PPG), Ajinomoto build-up film (ABF), photo imageable dielectric (PID), solder resist (SR), or the like, but an embodiment thereof is not limited thereto.

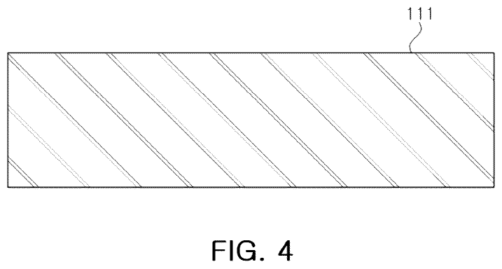

Hereinafter, an example of a process for manufacturing a printed circuit board will be described with reference to FIGS. 4 to 12. First, a process for forming a through-hole in a glass layer 111 will be described with reference to FIGS. 4 to 6. In FIG. 6, the glass layer 111 is shown in a plan view, while FIG. 5 is a cross-sectional diagram illustrating a partial region of FIG. 6. The glass layer 111 is prepared (FIG. 4), and a first through-hole H1 and a second through-hole H2 are formed in the glass layer 111, as illustrated in FIGS. 5 and 6. The through-holes H1 and H2 may be formed by processes such as etching, blasting, laser processing, or plasma treatment. The first through-hole H1 is a region in which a via conductor 120 is formed, and the second through-hole H2 corresponds to a dicing region for division into a unit region U. A bridge region B is formed to support the unit region U, and this bridge region corresponds to an area where the glass layer 111 is not completely penetrated in the thickness direction and remains intact. In the bridge region B, the side surface of the glass layer 111 is formed as an inclined surface.

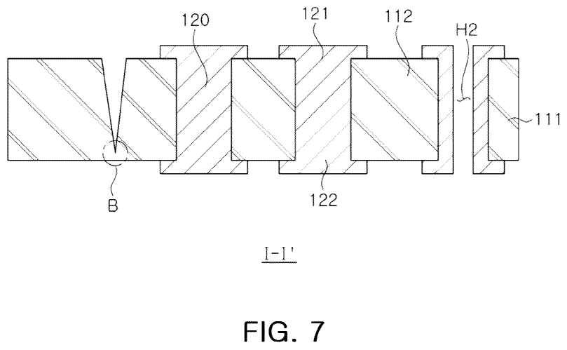

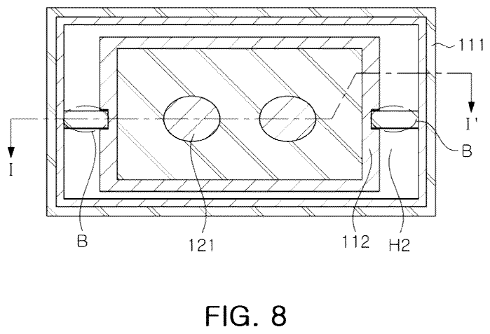

The process of forming the metal layer 112 and the via conductor 120 may be described with reference to FIGS. 7 and 8. FIG. 8 may be a plan diagram illustrating the glass layer 111 viewed from above, and FIG. 7 may be a cross-sectional diagram illustrating a partial region in FIG. 8. The via conductor 120 filling the first through-hole H1 of the glass layer 111 and the conductor layers 121 and 122 may be formed on an upper surface and a lower surface (corresponding to the first surface and the second surface described above, respectively) of the glass layer 111, respectively. Also, the metal layer 112 may be formed to cover the side surface, the upper surface and the lower surface of the glass layer 111. In this case, the metal layer 112 may be formed after a mask layer is formed on the upper surface such that the metal layer 112 is not formed in the bridge region B. Accordingly, the metal layer 112 on the side surface of the glass layer 111 may be separated by the bridge region B. As described later, the bridge region B may be removed in a subsequent process, and the second insulating layer 114 may be filled in the corresponding region, and accordingly, a structure in which the metal layer 112 is separated by the second insulating layer 114 may be obtained.

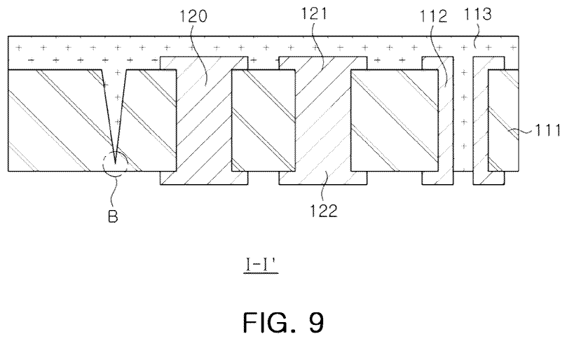

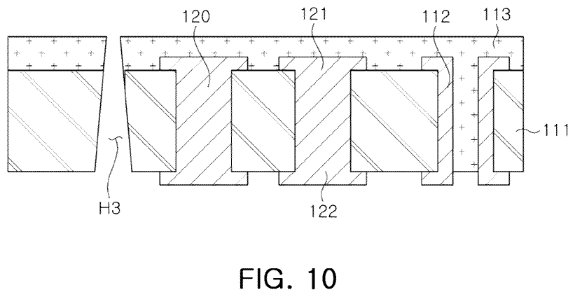

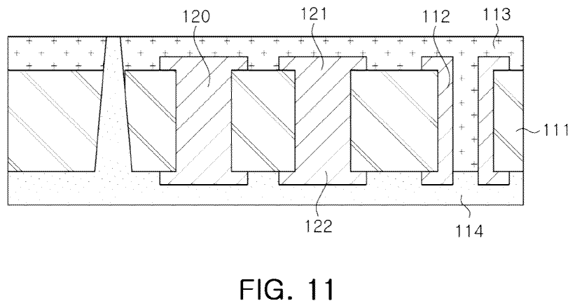

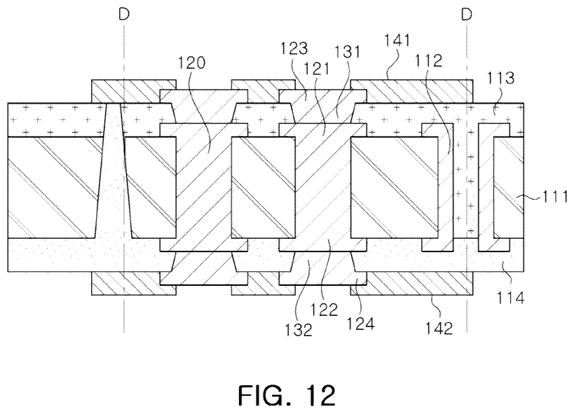

Thereafter, with reference to FIG. 9, the first insulating layer 113 is disposed on the upper surface of the glass layer 111 and is entirely filled in the second through-hole H2, which includes the bridge region B. Subsequently, referring to FIG. 10, a third through-hole H3 is formed such that at least a portion of the bridge region B is removed, thereby separating the glass layer 111 into individual units. Although not illustrated in the cross-sectional diagram in FIG. 10, as a plurality of bridge regions B (two bridge regions in the embodiment) are provided per unit U, a plurality of third through-holes H3 may also be formed. Thereafter, a second insulating layer 114 may be formed on the lower surface of the glass layer 111 and the third through-hole H3 (FIG. 11), conductor layers 123 and 124, via conductors 131 and 132, and passivation layers 141 and 142 may be formed (FIG. 12). Thereafter, a dicing process may be performed along a cutting line D to separate the elements by unit. In this case, the cutting line D may be beyond the glass layer 111, such that the first insulating layer 113 and the second insulating layer 114 may be cut.

Through the above-described processes, the printed circuit board 100 illustrated in FIG. 3 is obtained, and printed circuit boards according to modified examples may also be implemented by appropriately modifying the manufacturing method described above.

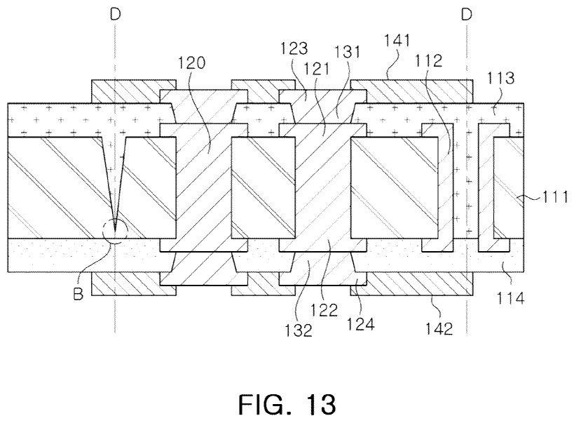

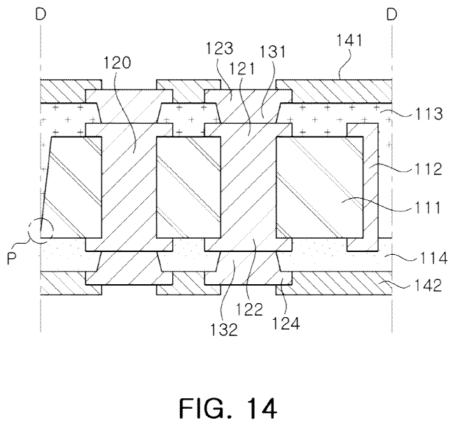

Differently from the above-described manufacturing process, the bridge region B may not be completely removed and may partially remain, which may be described with reference to FIGS. 13 and 14. FIG. 13 illustrates an example in which conductor layers 123 and 124, via conductors 131 and 132, and passivation layers 141 and 142 are formed in a state in which the bridge region B remains after the process in FIG. 9. Thereafter, a dicing process may be performed along the cutting line D to separate the elements by unit, and the cutting line D may be determined to include the bridge region B as illustrated in FIG. 13. FIG. 14 illustrates a printed circuit board in an individualized state, and the glass layer 111, the remaining region of the bridge region B, may include a protrusion P formed on the side surface. By including the protrusion B in the glass layer 111, the region of the glass layer 111 may be expanded, such that warpage properties may be addressed, and in this case, since the size of the protrusion B is relatively small, it may be difficult for cracks to propagate through the protrusion B.

According to the example embodiments described above, the occurrence of cracks in the glass layer of the printed circuit board may be reduced, thereby improving its reliability.

In the embodiment, the terms “covering” or “may cover” may include covering completely and also covering at least partly, and may also include covering directly and also covering indirectly. Also, the terms “filling” or “may fill” may include completely filling and also filling at least partly, and may also include roughly filling. For example, the example may include the case in which pores or voids are present. Also, the term “surrounding” may include completely surrounding and also partially surrounding and roughly surrounding. Also, “exposing” may include completely exposing and also partially exposing, and exposure may indicate exposure from the buried element. For example, the configuration in which the opening exposes the pad may indicate exposing the pad from the resist layer, and a surface treatment layer may be further disposed on the exposed pad.

In the embodiment, the configuration of being disposed in the through-portion or through-hole may include the configuration in which the object is disposed completely within the through-portion or through-hole, and also the configuration in which the object protrudes upwardly or downwardly in a cross-sectional. For example, when the object is disposed within the through-portion or through-hole on a plane, the configuration may be understood in a broader sense.

In the embodiment, process errors, positional deviations, and measurement errors occurring during the manufacturing process may be included. For example, the configuration of being substantially vertical may include being completely vertical, and also almost being vertical. Also, the configuration of being substantially coplanar may include the elements are completely present on the same plane, and also the configuration in which the elements are present almost on the same plane.

In the embodiment, the same insulating material may indicate the example in which insulating materials are completely the same, and also the example in which the material includes the same type of insulating material. Therefore, the composition of the insulating material may be substantially the same, and the specific composition ratio thereof may be slightly different.

In the embodiment, the term “on the cross-section” may refer to the cross-sectional shape observed when the object is cut in the vertical direction or viewed from the side. Similarly, the term “on the plane” may refer to the planar shape observed when the object is cut in the horizontal direction or viewed from the top or bottom.

In the embodiment, the terms “lower side,” “lower portion,” and “lower surface” may be used to indicate the downward direction based on the cross-section of the drawing for ease of description, and the terms “upper side,” “upper portion,” and “upper surface” may be used to indicate the opposite direction thereof. However, this is for ease of description, and the scope of the claims is not specifically limited by the description of the directions, and the concept of “upper/lower”may be varied.

In the embodiment, the configuration of being connected may include both direct connections and indirect connections (for example, through an adhesive layer). Additionally, the configuration of being electrically connected may encompass cases where elements are either physically connected or not connected. Furthermore, terms such as “first” and “second” are used solely to distinguish one component from another and do not imply any specific order or importance. In some instances, without exceeding the scope of the claims, the first component may be referred to as the second component, and vice versa.

In the embodiment, the thickness, width, length, depth, line width, spacing, pitch, separation distance, surface roughness, or the like, may be measured using a scanning microscope or an optical microscope based on a cross-section of a printed circuit board that has been polished or cut. The cross-section may be a vertical cross-section or a horizontal cross-section, and each value may be measured based on the required cross-section. For example, the width of the upper end and/or lower end of the via may be measured on a cross-section taken along the central axis of the via. In this case, when the value is not constant, the value may be determined as an average value of values measured at five arbitrary points.

The term “an example” used in the embodiment does not indicate the same embodiments, and may be provided to describe and emphasize each unique feature. However, the examples be implemented by being combined with features of other examples. For example, a matter described in a particular example may be understood as being related to another example even when it is not described in another example unless otherwise indicated.

The terms may be defined as above for ease of description, and the scope of right of the example embodiments is not particularly limited to the above terms. term used in the singular encompasses the term of the plural, unless it has a clearly different meaning in the context.

While the example embodiments have been illustrated and described above, it will be apparent to those skilled in the art that modifications and variations may be made without departing from the scope of the present disclosure, as defined by the appended claims.

What is claimed is:

1. A printed circuit board, comprising:
a glass layer having a first surface and a second surface opposing each other in a thickness direction, and a side surface connected to the first surface and the second surface;
a metal layer disposed on a side surface of the glass layer; and
a first insulating layer disposed on the first surface and the side surface of the glass layer,
wherein the first insulating layer covers the metal layer on the side surface of the glass layer.

2. The printed circuit board of claim 1, wherein the metal layer is disposed on at least a portion of the first surface and the second surface of the glass layer.

3. The printed circuit board of claim 1, wherein the first insulating layer is disposed in a region of the side surface of the glass layer, in which the metal layer is not disposed.

4. The printed circuit board of claim 3, wherein an area of the metal layer, covering the side surface of the glass layer, is greater than that of the first insulating layer.

5. The printed circuit board of claim 1, wherein a region of the side surface of the glass layer, in which the metal layer is not disposed, is inclined relative to the thickness direction.

6. The printed circuit board of claim 5, wherein the region of the side surface of the glass layer, in which the metal layer is not disposed, comprises a plurality of regions having different angles of inclination relative to the thickness direction.

7. The printed circuit board of claim 6, wherein the region of a side surface of the glass layer, in which the metal layer is not disposed, has a shape in which a width of the glass layer increases and then decreases in a direction from the first surface to the second surface.

8. The printed circuit board of claim 5, wherein the region of the side surface of the glass layer, in which the metal layer is not disposed, is more inclined in the thickness direction than a region in which the metal layer is disposed.

9. The printed circuit board of claim 1, further comprising:
a second insulating layer disposed on both the second surface and the side surface of the glass layer.

10. The printed circuit board of claim 9, wherein an area of the metal layer, covering the side surface of the glass layer, is greater than that of the second insulating layer.

11. The printed circuit board of claim 9, wherein the metal layer is separated from the side surface of the glass layer by the second insulating layer.

12. The printed circuit board of claim 11, wherein, in the second insulating layer, a region disposed on the side surface of the glass layer comprises a plurality of regions that are separated from each other.

13. The printed circuit board of claim 9, wherein side surfaces of the first and second insulating layers are coplanar.

14. The printed circuit board of claim 9, wherein the first insulating layer and the second insulating layer are formed from the same material and are in contact with one another, thereby forming an interfacial surface.

15. The printed circuit board of claim 1, wherein the glass layer comprises a protrusion formed on the side surface.

16. A printed circuit board, comprising:
a glass layer having a first surface and a second surface opposing each other in a thickness direction, and a side surface connected to the first surface and the second surface;
a metal layer disposed in a first region of the side surface of the glass layer; and
an insulating layer comprising a material different from that of the glass layer and disposed in a second region of the side surface of the glass layer.

17. The printed circuit board of claim 16, wherein an area of the first region is larger than an area of the second region.

18. A printed circuit board, comprising:
a glass layer having a first surface and a second surface opposing each other in a thickness direction, and a side surface connected to the first and the second surfaces;
a metal layer disposed on the side surface of the glass layer;
a via conductor formed by filling a conductive material in a first through-hole of the glass layer, the via conductor being electrically connected to the metal layer; and
a first insulating layer disposed on the first surface and the side surface of the glass layer, wherein the first insulating layer covers the metal layer on the side surface of the glass layer.

19. The printed circuit board of claim 18, wherein the via conductor comprises a seed layer.
